(19) United States
(12) Patent Application Publication
(10) Pub. No.: US 2017/0070693 A1
(43) Pub. Date: Mar. 9, 2017

(54) IMAGE SENSOR ADAPTED MULTIPLE FILL FACTOR

(71) Applicants: Center for Integrated Smart Sensors Foundation, Daejeon (KR); Dual Aperture International Co., Ltd., Gyeonggi-do (KR)

(72) Inventors: Junho MUN, Gyeonggi-do (KR); Jong HO PARK, Daejeon (KR)

(21) Appl. No.: 15/255,839

(22) Filed: Sep. 2, 2016

(30) Foreign Application Priority Data
Sep. 4, 2015 (KR) PCT/KR2015/009329

(51) Int. Cl. H04N 5/365; H04N 5/355; H04N 9/04; H01L 27/146

(52) U.S. Cl. CPC H04N 5/3656; H01L 27/14605; H04N 5/355; H01L 27/14627; H01L 27/14645; H04N 9/045

(57) ABSTRACT

Disclosed is an image sensor adapting multiple fill factors. The image sensor includes a plurality of pixels configured to process light rays having a plurality of wavelengths by wavelength, wherein at least one of the pixels has a fill factor which is different from fill factors of remaining pixels other than the at least one pixel.

### CROSS-REFERENCE TO RELATED APPLICATIONS

This application claims the benefit under 35 U.S.C. §119(a) of a PCT international application filed on Sep. 04, 2015 and assigned Serial number PCT/KR2015/009329, the entire disclosure of which is hereby incorporated by reference.

### BACKGROUND

Embodiments of the inventive concept described herein relate to an image sensor adapting multiple fill factors, and more particularly, relate to a technique of applying mutually different fill factors to a plurality of pixels included in an image sensor (hereinafter, the fill factor represents a ratio of an area occupied by an optical diode in a pixel).

An image sensor according to the related art includes a plurality of pixels having the same fill factor. Thus, the image sensor according to the related art cannot perform any application functions, such as a refocusing function, a high-dynamic-range imaging function, a depth extraction function, etc., except for a general function of processing a light ray to obtain an image.

In addition, the image sensor according to the related art requires an additional aperture to perform an application function as well as a basic aperture.

Thus, following embodiments disclose an image sensor which performs an application function by applying fill factors of a plurality of pixels different from each other.

### SUMMARY

Embodiments of the inventive concept provide an image sensor to which pixels having mutually different fill factors are applied.

In details, embodiments of the inventive concept provide an image sensor in which an optical diode included in at least one of pixels is arranged to be offset against optical diodes included in the remaining pixels.

In addition, embodiments of the inventive concept provide an image sensor which is adjusted such that a depletion region of an optical diode included in at least one of pixels is formed to be offset against those of optical diodes of the remaining pixels.

Therefore, embodiments of the inventive concept may perform an application function such as refocusing, high-dynamic range imaging, depth extraction, etc., based on a disparity between images obtained through at least one of pixels and the remaining pixels.

In addition, embodiments of the inventive concept provides an image sensor in which at least one of pixels includes an optical diode which has a size smaller than those of optical diodes included in the remaining pixels

In addition, embodiments of the inventive concept provides an image sensor in which an optical diode included in at least one of pixels has a ray incident area smaller than those of optical diodes included in the remaining pixels, such that only light rays corresponding to a central portion of a bundle of light rays are incident upon the optical diode of the at least one pixel.

Thus, embodiments of the inventive concept may perform an application function, such as refocusing, high-dynamic range imaging, depth extraction, etc., based on a blur change between images obtained through at least one of pixels and the remaining pixels

According to an aspect of an embodiment, there is provided an image sensor to which multiple fill factors are applied, which includes a plurality of pixels configured to process light rays having a plurality of wavelengths by wavelength, wherein at least one of the pixels has a fill factor which is different from those of remaining pixels other than the at least one pixel.

A position of an optical diode included in the at least one pixel may be offset against positions of optical diodes included in the remaining pixels.

A position of a depletion region formed in an optical diode included in the at least one pixel may be offset against positions of depletion regions formed in optical diodes included in the remaining pixels.

The image sensor may perform depth extraction based on a disparity between an image obtained through the at least one pixel and images obtained through the remaining pixels.

The image sensor may perform refocusing using a disparity between an image obtained through the at least one pixel and images obtained through the remaining pixels.

The at least one pixel may include an optical diode which has a size smaller than sizes of optical diodes included in the remaining pixels.

The optical diode included in the at least one pixel may have a ray incident area smaller than ray incident areas of the optical diodes included in the remaining pixels, such that only light rays corresponding to a circumferential portion of a bundle of light rays are incident upon the optical diode of the at least one pixel.

A size of a depletion region formed in an optical diode included in the at least one pixel may be adjusted such that the size of the depletion region formed in the optical diode included in the at least one pixel is different from sizes of depletion regions formed in optical diodes included in the remaining pixels.

The image sensor may perform high-dynamic range imaging by using images obtained through the at least one pixel and the remaining pixels.

The image sensor may perform depth extraction based on a blur change between images through the at least one pixel and the remaining pixels.

The image sensor may further include a metal layer arranged between a micro-lens and an optical diode included in the at least one pixel to reduce a ray incident area of the optical diode, wherein a hole is formed in the metal layer.

The pixels may include micro-lenses having a same form or size.

The pixels may include a red cell, a green cell, a blue cell and a white cell, wherein the white cell may have a fill factor different from fill factors of the red, green and blue cells.

The pixels may include a red cell, two green cells and a blue cell, wherein one of the two green cells has a fill factor different from fill factors of the red cell, the other green cell and the blue cell.

According to another aspect of an embodiment, there may be provided an image sensor to which pixels having mutually different fill factors are applied.

In details, embodiments of the inventive concept provide an image sensor in which an optical diode included in at least one of pixels is arranged to be offset against optical diodes included in the remaining pixels.

In addition, embodiments of the inventive concept provide an image sensor which is adjusted such that a depletion region of an optical diode included in at least one of pixels is formed to be offset against those of optical diodes of the remaining pixels.

Therefore, embodiments of the inventive concept may perform an application function such as refocusing, high-dynamic range imaging, depth extraction, etc., based on a disparity between images obtained through at least one of pixels and the remaining pixels.

In addition, embodiments of the inventive concept provides an image sensor in which at least one of pixels includes an optical diode which has a size smaller than those of optical diodes included in the remaining pixels.

In addition, embodiments of the inventive concept provides an image sensor in which an optical diode included in at least one of pixels has a ray incident area smaller than those of optical diodes included in the remaining pixels, such that only light rays corresponding to a central portion of a bundle of light rays are incident upon the optical diode of the at least one pixel.

Thus, embodiments of the inventive concept may perform an application function, such as refocusing, high-dynamic range imaging, depth extraction, etc., based on a blur change between images through at least one of pixels and the remaining pixels.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIGS. 1A and 1B are views illustrating a bundle of light rays incident upon an image sensor according to a position of the image sensor according to an embodiment;

FIG. 2 is a view illustrating an image sensor according to an embodiment;

FIGS. 3A and 3B are views illustrating pixels arranged on a central portion and a circumferential portion of a bundle of light rays according to an embodiment;

FIGS. 4A and 4B are views showing an image obtained by an image sensor according to an embodiment;

FIG. 5 is a view showing a pixel included in an image sensor according to another embodiment;

FIGS. 6A and 6B are views illustrating the details of the image sensor depicted in FIG. 2;

FIGS. 7A and 7B are views illustrating pixels arranged on a central portion and a circumferential portion of a bundle of light rays according to another embodiment;

FIGS. 8A and 8B are views illustrating pixels arranged on a central portion and a circumferential portion of a bundle of light rays according to still another embodiment;

FIG. 9 is a view illustrating the disparity between images obtained from the plurality of pixels depicted with reference to FIGS. 8A and 8B; and

FIG. 10 is a view showing another example of the pixels depicted with reference to FIGS. 8A and 8B.

### DETAILED DESCRIPTION

Hereinafter embodiments of the inventive concept will be described in detail with reference to the accompanying drawings. But, it should be understood that the inventive concept is not limited to the following embodiments. In addition, the same reference numerals used in each drawing r, resent the same elements.

In addition, terminologies used herein are defined to appropriately describe the exemplary embodiments of the inventive concept and thus may be changed depending on a user, the intent of an operator, or a custom. Accordingly, the terminologies must be defined based on the following overall description of this disclosure.

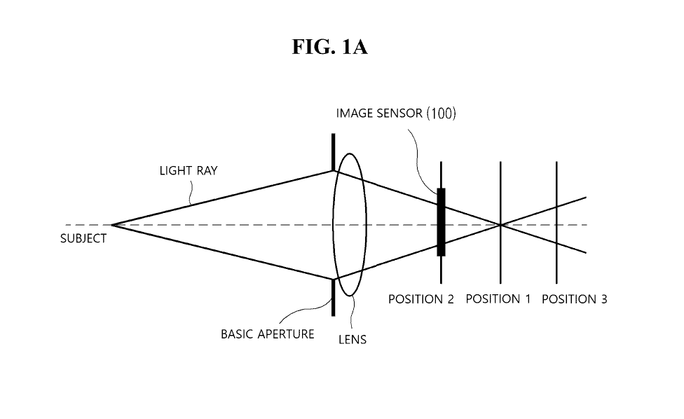

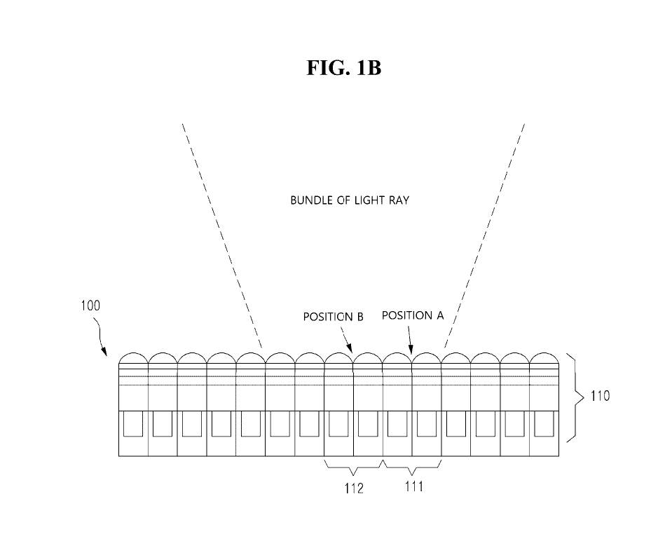

FIGS. 1A and 1B are views illustrating a bundle of light rays incident upon an image sensor according to a position of the image sensor according to an embodiment.

In detail, FIG. 1A is a view illustrating a correlation between a position of the image sensor 100 and a focus of the image obtained through the image sensor 100 according to an embodiment. FIG. 1B is a view showing a bundle of light rays incident upon the image sensor 100 placed at position 2 depicted in FIG. 1A.

Referring to FIG. 1A, in a camera system according to an embodiment, the light rays having a plurality of wavelengths are incident upon the image sensor 100 through a basic aperture and a lens. In this case, when the image sensor 100 is arranged at position 1, the image sensor 100 may process the light rays by wavelength to obtain a well-focused fine image.

Meanwhile, when the image sensor 100 is placed at position 2 or 3, the image sensor 100 may process the light rays by wavelength to obtain a defocused blurred image.

Thus, referring to FIG. 1B, when the image sensor 100 is placed at position 2, the bundle of light rays may be incident upon the image sensor 100 as shown in FIG. 1B. Thus, when mutually different fill factors are applied to the pixels 111, which are arranged at position A corresponding to a circumferential portion of the bundle of light rays among the pixels 110 included in the image sensor 100, light rays having mutually different light quantities may be incident upon the pixels 111 arranged at potions A (Meanwhile, light rays having the same light quantity may be incident upon pixels 112 arranged at position B corresponding to the central portion of the bundle of light rays among the pixels 110).

Hereinafter, a scheme of allowing light rays having mutually different light quantities to be incident upon the pixels 111 arranged at position A corresponding to the circumferential portion of the bundle of light rays by applying mutually different fill factors to the pixels 111 arranged at position A among the pixels 110 will be described in detail.

In addition, the fact that the fill factors of the pixels are different from each other may imply that the ratios between the light-ray processing regions and the entire pixel regions in the pixels are different from each other and the positions at which the light-ray processing regions of the pixels are placed are different from each other.

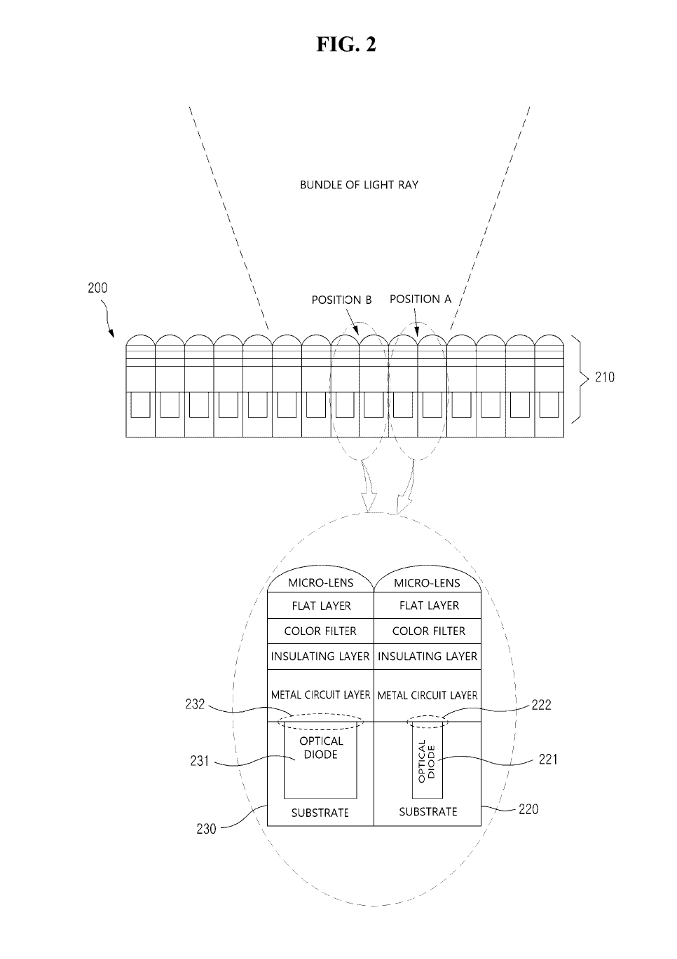

FIG. 2 is a view illustrating an image sensor according to an embodiment.

Referring to FIG. 2, an image sensor 200 according to an embodiment includes a plurality of pixels 210 configured to process a light ray having a plurality of wavelengths by wavelength.

In this case, the pixels 210 may constitute one set and the image sensor 200 may include a plurality of sets. For example, a set having pixels 210 may be arranged at position A corresponding to a circumferential portion of a bundle of light rays incident upon the image sensor 200 or position B corresponding to a central portion of the bundle of light rays incident upon the image sensor 200.

Each of the pixels 210 may include a micro-lens, a flat layer, a color filter, an insulating layer, a metal circuit layer, an optical diode, and a substrate. In this case, although each of the pixels 210 necessarily includes the micro-lens, the color filter and the optical diode, the flat layer, the insulating layer, the metal circuit layer, and the substrate are optionally included in each of the pixels 210.

The color filter included in each pixel 210 may filter out the light rays having wavelengths other than a specific wavelength such that each of the pixels 210 processes the light rays by wavelength and may allow only the light ray having the specific wavelength to pass therethrough.

Specifically, the micro-lenses included in the pixels 210 may have the same form or size, but fill factors applied to the pixels 210 may be different from each other. For example, at least one pixel 220 of the pixels 210 may have a fill factor less than those of the remaining pixels 230.

In this case, the at least one pixel 220 may include an optical diode 221 having a size smaller than those of optical diodes 231 included in the remaining pixels 230, so that the at least one pixel 220 has a fill factor less than those of the remaining pixels 230.

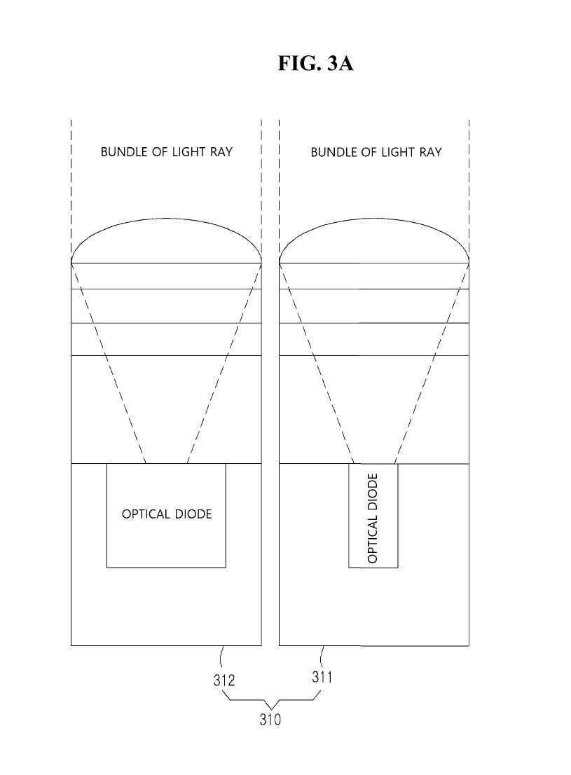

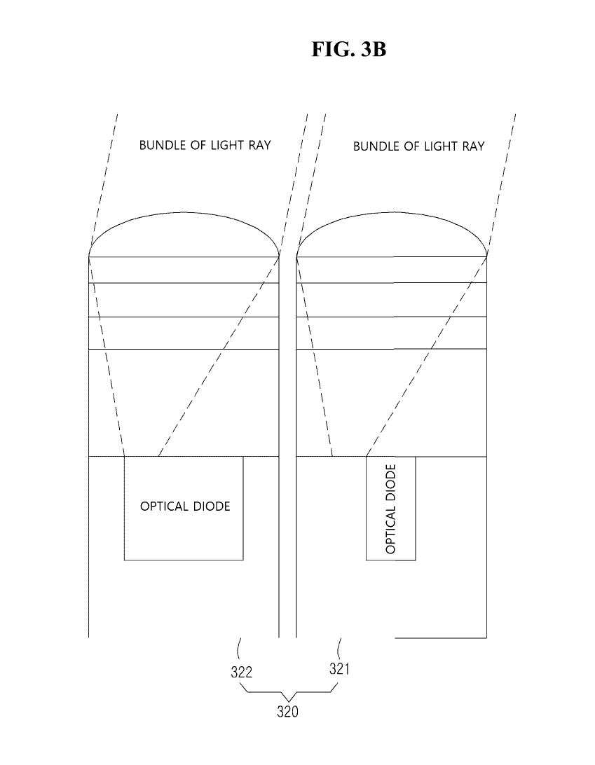

Thus, the optical diode 221 included in the at least one pixel 220 may have an incident area smaller than those 232 of the optical diodes 231 included in the remaining pixels 230 such that only the light rays corresponding to the central portion of the bundle of light rays are incident upon the optical diode 221 of the at least one pixel 220. The details will be described with reference to FIGS. 3A and 3B.

FIGS. 3A and 3B are views illustrating pixels arranged on a central portion and a circumferential portion of the bundle of light rays according to an embodiment.

In detail, FIG. 3A is a view illustrating a case that a plurality of pixels 310 according to an embodiment is arranged at a central portion of the bundle of light rays. FIG. 3B is a view illustrating a case that a plurality of pixels 320 according to an embodiment is arranged at a circumferential portion of the bundle of light rays.

Referring to FIG. 3A, the light rays having the same light quantity may be incident upon the pixels 310 arranged at the central portion (position B of FIG. 2) of the bundle of light rays without regard to the fill factors of the pixels 310 (without regard to the sizes of the optical diodes included in the pixels 310).

For example, the light rays corresponding to the central portion of the bundle of light rays may be fully incident upon at least one pixel 311 (which includes an optical diode having a small size and to which a lower fill factor is applied) among the pixels 310 arranged at the central position of the bundle of light rays, and may be fully incident upon even the remaining pixels 312 (which include optical diodes having large sizes and to which high fill factors are applied). Hereinafter, the fact that an optical diode is small or large implies that the optical diode has a size smaller than those of optical diodes included in other pixels. In addition, the fact that a fill factor is low implies that the fill factor is lower than fill factors applied to other pixels.

In this case, since the at least one pixel 311 has an optical diode having a small size, a ray incident area of the at least one pixel 311 may be smaller than those of the remaining pixels 312 including optical diodes having large sizes.

Meanwhile, referring to FIG. 3B, according to the embodiment, light rays having mutually different light quantities may be incident upon the pixels 320 arranged at the circumferential portion (position A of FIG. 2) of the bundle of light rays according to the fill factors of the pixels 320 (the sizes of the optical diodes included in the pixels 320).

For example, the light rays (which are bur rays capable of causing a blurring phenomenon) of the circumferential portion of the bundle of light rays may be incident upon not at least one 321 (which include an optical diode having a small size and to which a low fill factor is applied) among the pixels 320 arranged at the circumferential portion of the bundle of light rays, but fully the remaining pixels 322 (which include optical diodes having large sizes and to which high fill factors are applied).

In this case, since the at least one pixel 321 includes an optical diode of a small size, the ray incident area of the at least one pixel 321 may be smaller than those of the remaining pixels 322 including optical diodes of large sizes.

That is, since the at least one pixel 311 or 321 of the pixels 310 or 320 includes an optical diode having a size smaller than those of the optical diodes include in the remaining pixels 312 or 322, only the light rays of the central portion of the bundle of light rays may be incident upon the at least one pixel 311 or 321 (but the rays of the circumferential portion of the bundle of light rays are not incident) and all the light rays of the central and circumferential portions of the bundle of light rays may be incident upon the remaining pixels 312 or 322.

Thus, the image sensor including the pixels 310 or 320 may perform an application function such as refocusing, high-dynamic range imaging, depth extraction, etc., by using the at least one pixel 311 or 321 and the remaining pixels 312 or 322. The details will be described below.

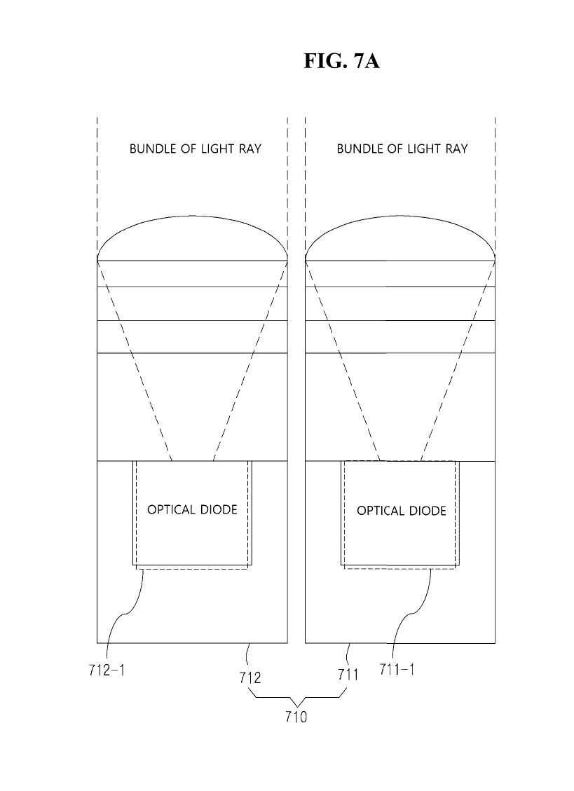

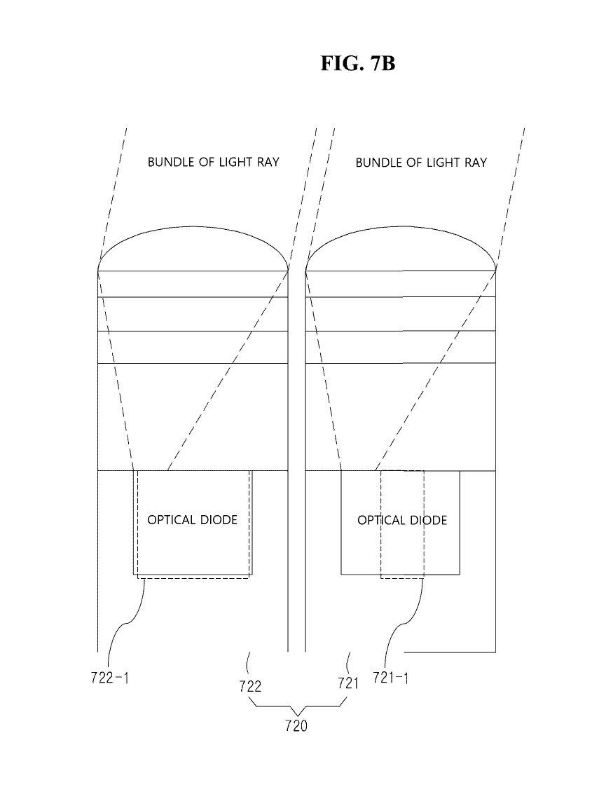

As described above, although it has been described that the optical diode included in the at least one pixel 311 is formed to have a physical size smaller than those of the optical diodes included in the remaining pixels 312 so that the fill factor of the at least one pixel 311 is less than those of the remaining pixels 312, without changing the physical size of the optical diode included in the at least one pixel 311, the fill factor of the at least one pixel 311 may be lower than those of the remaining pixels 312 by adjusting a size of a depletion region of the optical diode included in the at least one pixel 311 to be smaller than those of the optical diodes included in the remaining pixels 312, so that the fill factor of the at least one pixel 311 may be smaller than those of the remaining pixels 312. The details will be described below with reference to FIGS. 7A and 7B.

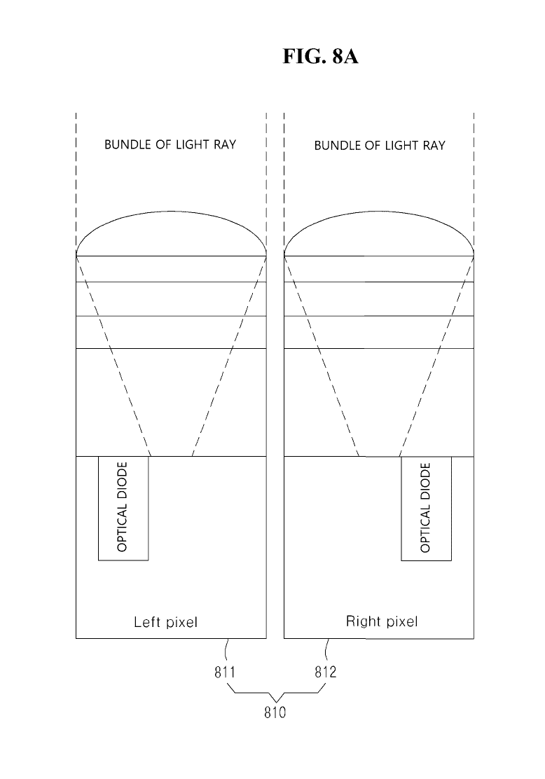

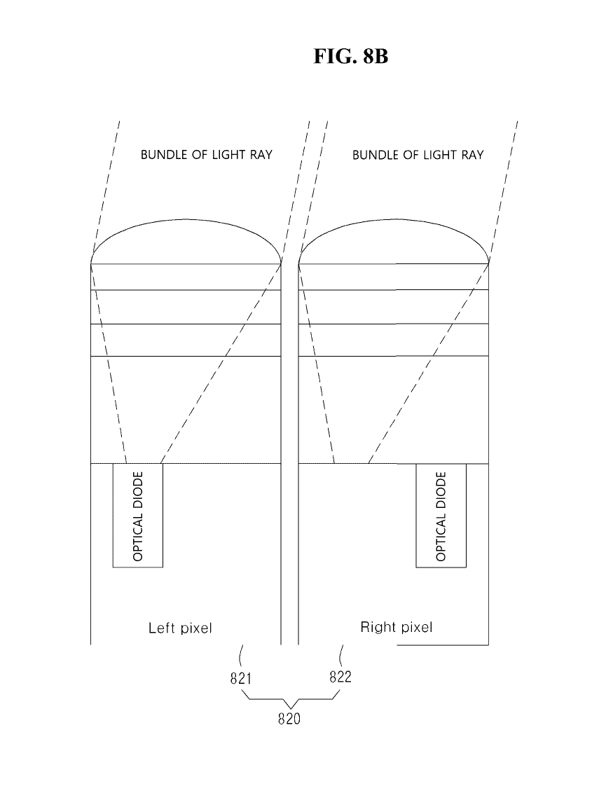

In addition, the position of the optical diode included in the at least one pixel 311 is offset against the positions of the optical diodes included in the remaining pixels 312, or the position of the depletion region of the optical diode included in the at least one pixel 311 is adjusted to be different from those of the depletion regions of the optical diodes included in the remaining pixels 312, so that the fill factor of the at least one pixel 311 is different from those of the remaining pixels 312 (a region of the at least one pixel 311 in which light rays are processed is different from regions of the remaining pixels 312 in which light rays are processed). The details will be described below with reference to FIGS. 8A, 8B, 9 and 10.

Hereinafter, the fact that the positions at which optical diodes are placed in a plurality of pixels are offset against each other implies that the optical diodes are placed at mutually different positions (which are based on the center of each pixel) in the pixels. In addition, the fact that the positions at which the depletion regions of optical diodes are formed in a plurality of pixels are offset against each other implies that the depletion regions of the optical diodes are formed at mutually different positions (which are based on the center of each pixel) in the pixels.

In addition, hereinafter, the fact that the fill factors of at least one pixel 311 is different from those of the remaining pixels 312 implies that a property of an optical diode included in the at least one pixel 311 is different from those of optical diodes of the remaining pixels 312.

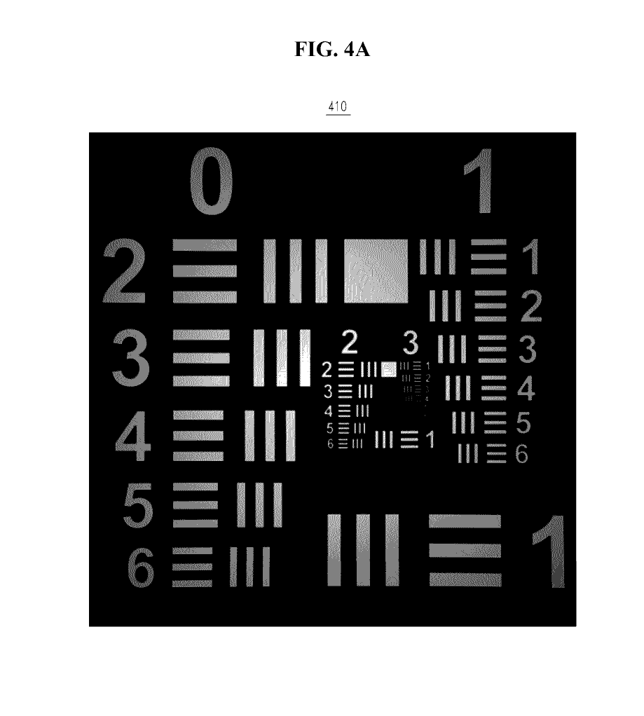

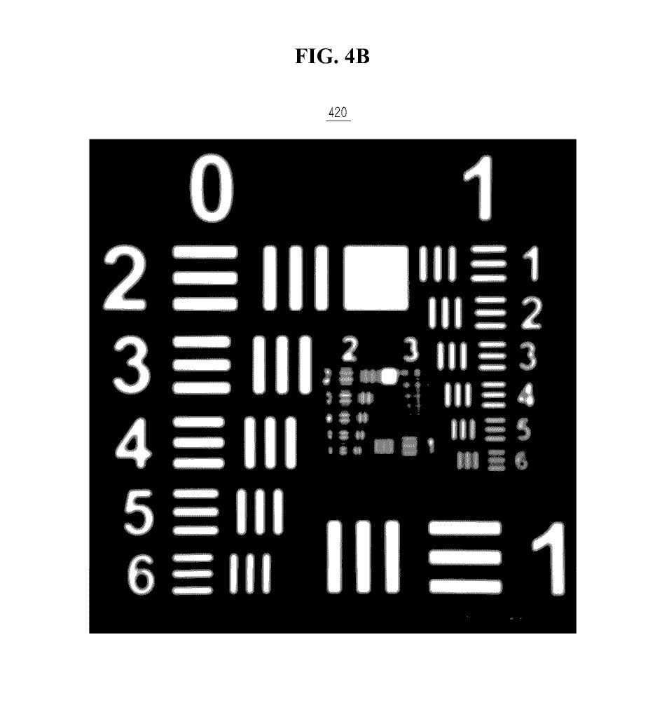

FIGS. 4A and 4B are views showing an image obtained by an image sensor according to an embodiment.

In detail, FIG. 4A shows an image obtained through a pixel having a low fill factor according to an embodiment. FIG. 4B shows an image obtained through a pixel having a high fill factor according to an embodiment.

Referring to FIG. 4A, according to an embodiment, since only the light rays corresponding to the central portion of the bundle of light rays is incident upon a pixel having a low fill factor (which is at least one pixel which includes an optical diode having a small size and to which a low fill factor is applied as described with reference to FIG. 3A and 3B), the pixel having a low fill factor may generate a fine image 410.

Meanwhile, referring to FIG. 4B, according to an embodiment, since all the light rays corresponding to the central and circumferential portions of the bundle of light rays are incident upon a pixel having a high fill factor (which is the remaining pixels which include optical diodes having large sizes and to which high fill factors are applied as described with reference to FIG. 3A and 3B), the pixels having high fill factors may generate an (blurred) image 420 blurrier than the image 410 generated by the pix having a low fill factor and depicted in FIG. 4A.

Therefore, the image sensor according to an embodiment may be refocused by using the images 410 and 420 obtained through the at least one pixel having a low fill factor and the remaining pixels having high fill factors.

In addition, the image sensor may perform high-dynamic range imaging by using the images 410 and 420 obtained through the at least one pixel having a low fill factor and the remaining pixels having high fill factors (by using the feature that the quantity of light incident upon the at least one pixel having a low fill factor is smaller than that incident upon the remaining pixels having high fill factors).

In addition, the image sensor may perform depth extraction based on a blur change between the images 410 and 420 obtained through the at least one pixel having a low fill factor and the remaining pixels having high fill factors.

Thus, the image sensor may perform application functions such as refocusing, high-dynamic range imaging, depth extraction, etc., without any additional elements (such as an additional aperture, etc.) by changing only the fill factors of the optical diodes included in the pixels.

In addition, instead of allowing the optical diodes included in the pixels to have low or high fill factors such that the fill factors are different from each other, the image sensor may be adjusted to allow the optical diodes included in the pixels to be offset against each other or the depletion regions of the optical diodes to be offset against each other, such that the properties of the optical diodes included in the pixels are different from each other. The details will be described below with reference to FIGS. 8A, 8B, 9 and 10.

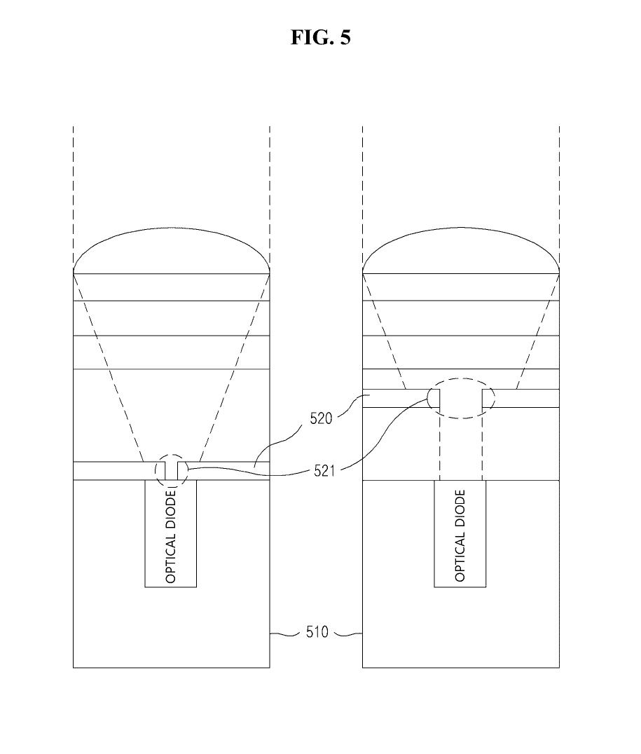

FIG. 5 is a view showing a pixel included in an image sensor according to another embodiment.

Referring to FIG. 5, the image sensor according to another embodiment includes a plurality of pixels which process light rays having a plurality of wavelengths by wavelength.

In this case, a metal layer 520 may be arranged at at least one pixel 510 (which includes an optical diode having a small size and to which a lower fill factor is applied) among the plurality of pixels.

For example, the metal layer 520 may be interposed between a micro-lens and an optical diode included in the at least one pixel, but the embodiment is not limited thereto. The metal layer 520 may be placed over the optical diode included in the at least one pixel 510.

In this case, the metal layer 520 includes a hole 521 which is formed in a circular or polygonal shape (for example, when viewed from top of the metal layer 520, the hole 521 may have a circular or polygonal shape). Thus, since light rays are incident upon the optical diode through the hole 521 of the metal layer 520, a light-ray incident area of the optical diode included in the at least one pixel 510 may be reduced.

As described above, since the at least one pixel 510 further includes the metal layer 520, the image obtained through the at least one pixel 510 may be finer (darker) than that obtained through a pixel having no metal layers. Thus, the image sensor according to another embodiment includes the metal layer 520 provided to at least one 510 of pixels, so that the image sensor may more easily perform an application function such as refocusing, high-dynamic range imaging, depth extraction, etc.

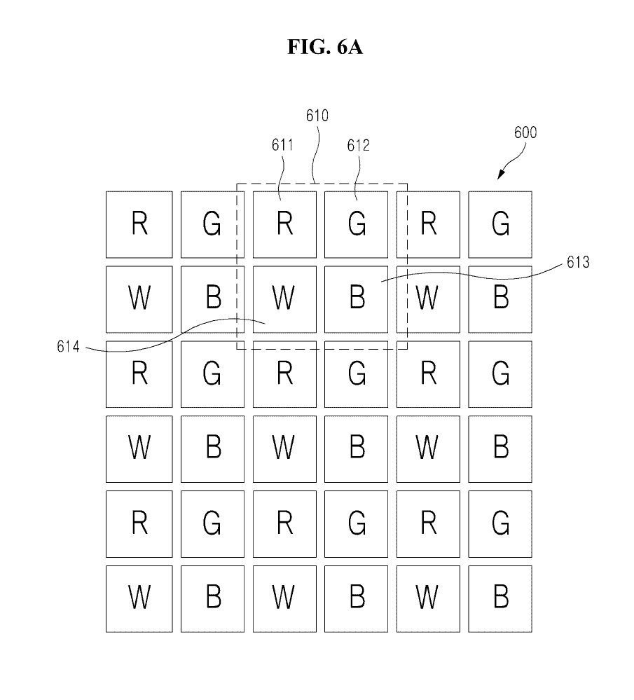

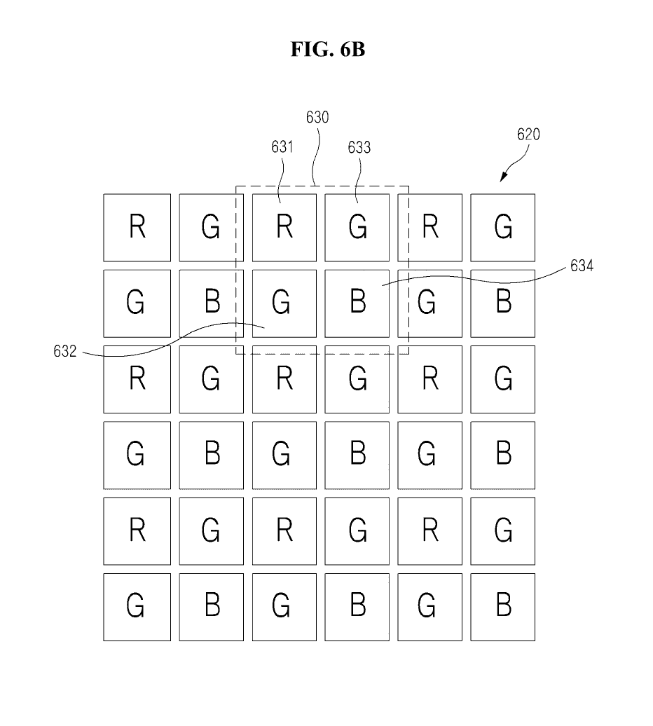

FIGS. 6A and 6B are views illustrating the details of the image sensor depicted in FIG. 2.

In detail, FIG. 6A shows an image sensor 600 including R, G, B and W cells according to an embodiment.

Referring to FIG. 6A, when each of pixels 610 included in the image sensor 600 according to an embodiment includes red (R), green (G), blue (B) and white (W) cells 611 to 613, the W cell 614 may have a fill factor different from those of the R, G and B cells 611 to 613. That is, as described above, since the W cell 614 includes an optical diode having a size smaller than that of an optical diode included in each of the remaining pixels (R, G and B cells 611 to 613), the W cell 614 may have a lower fill factor than that of each of the remaining pixels (R, G and B cells 611 to 613).

FIG. 6B shows an image sensor 620 including R, two G, B and W cells according to another embodiment.

Referring to FIG. 6B, when each of pixels 630 included in the image sensor 620 according to another embodiment includes R, two G, and B cells 631 to 634, one of the two G cells 632 and 633 may have a fill factor different from those of the R cell 631, the remaining G cell 633 and the B cell 634. That is, as described above, since the one G cell 632 includes an optical diode having a size smaller than that of an optical diode included in each of the remaining pixels (R, remaining G and B cells 631, 633 and 634), the one G cell 632 may have a lower fill factor than that of each of the remaining pixels (R, remaining G and B cells 631, 633 and 634).

However, the embodiment is not limited to the above. The image sensor 600 or 620 may include pixels for processing light rays having several wavelengths and at least one of the pixels for processing light rays having several wavelengths may have a fill factor different from those of the remaining pixels.

FIGS. 7A and 7B are views illustrating pixels arranged on a central portion and a circumferential portion of a bundle of light rays according to another embodiment.

In detail, FIG. 7A is a view illustrating a case that a plurality of pixels 710 according to another embodiment is arranged at a central portion of a bundle of light rays. FIG. 7B is a view illustrating a case that a plurality of pixels 720 according to another embodiment is arranged at a circumferential portion of the bundle of light rays.

Referring to FIG. 7A, the pixels 710 arranged at the central portion (position B of FIG. 2) of the bundle of light rays according to another embodiment may be provided with depletion regions 711-1 and 712-1 formed on optical diodes in the same size at the same position, so that the pixels 719 receive light rays of the same light quantity.

For example, at least one pixel 711 among the pixels 710 arranged at the central portion of the bundle of light rays and the remaining pixels 712 may include optical diodes having the same size, and the positions and sizes of the depletion regions 711-1 and 712-1 are adjusted to be the same, so that the light rays of the central portion may be fully received.

Meanwhile, referring to FIG. 7B, according to another embodiment, the light rays having mutually different quantities may be incident upon the pixels 720 arranged at the circumferential portion (position A of FIG. 2) of the bundle of light rays according to the fill factors of the pixels 720 (depletion regions 721-1 and 722-1 of the optical diodes included in the pixels 720).

For example, the size of the depletion region 721-1 formed on the optical diode is adjusted to be small such that the at least one pixel 721 of the pixels 720 arranged at the circumferential portion of the bundle of light rays does not receive the light rays (which cause blur) of the circumferential portion of the bundle of light rays. The depletion region 722-1 formed on the optical diode is adjusted to be large, such that the remaining pixels 722 may fully receive the light rays of the circumferential portion.

That is, the at least one pixel 711 or 721 of the pixels 710 and 720 may receive only the light rays of the central portion and may not receive the light rays of the circumferential portion by adaptively adjusting the size of the depletion region 721-1 to be different from the sizes of the depletion regions 712-1 or 722-1 of the optical diode.

Hereinafter, the size or positon of the depletion region 721-1 or 722-1 may be adjusted by controlling a voltage applied to the optical diode, but the embodiment is not limited thereto. The size or positon of the depletion region 721-1 or 722-1 may be adjusted by controlling various parameters which exert influences upon the formation of the depletion region 721-1 or 722-1.

Therefore, as described with reference to FIGS. 4A and 4B, the image sensor including the pixels 710 and 720 may perform an application function, such as refocusing, high-dynamic range imaging, depth extraction, etc., by using the at least one pixel 711 or 721 and the remaining pixels 712 and 722.

Although not shown, in FIG. 7B, instead of adjusting the size of the depletion region 721-1 formed on the optical diode to be small, the position at which the depletion region 721-1 is formed may be adjusted on the optical diode such that at least one pixel 721 is prevented from receiving the light rays of the circumferential portion (for example, the depletion region 721-1 is adjusted to be located at the right side on the optical diode such that the light rays of the circumferential portion is prevented from being incident upon the depletion region 721-1).

Although it has been described above that the image sensor is configured to allow the optical diodes included in the pixels to have low or high fill factors, the image sensor may be configured to allow the optical diodes included in the pixels to be offset against each other. That is, the position at which the optical diode included in at least one of the pixels is arranged on the at least one pixel may be offset against positions at which the optical diode included in the remaining pixels are arranged on the remaining pixels. The details will be described below.

FIGS. 8A and 8B are views illustrating pixels arranged on a central portion and a circumferential portion of a bundle of light rays according to still another embodiment.

In detail, FIG. 8A is a view illustrating a case that a plurality of pixels 810 according to still another embodiment is arranged at a central portion of a bundle of light rays. FIG. 8B is a view illustrating a case that a plurality of pixels 820 according to still another embodiment is arranged at a circumferential portion of the bundle of light rays.

Referring to FIG. 8A, since the pixels 810 arranged at the central portion (position B of FIG. 2) of the bundle of light rays according to still another embodiment includes optical diodes which are arranged at positions (for example, left and right sides about the centers of pixels) offset against each other, light rays are not incident upon the pixels 810. Although it will be described below that the optical diodes are arranged at the left and right sides about the centers of the pixels, the embodiment is not limited thereto. The optical diodes may be arranged at mutually different positions on three-dimensional plane about the centers of the pixels.

For example, the light rays of the central portion of the bundle of light rays may not be incident upon at least one pixel 811 (in which an optical diode is formed at the left side about it) of the pixels 810 arranged at the central portion of the bundle of light rays, and may not be incident upon even the remaining pixels 812 (in which optical diodes are arranged at the right sides about them).

Meanwhile, referring to FIG. 8B, the light rays of mutually different light quantities may be incident upon the pixels 820 arranged at the circumferential portion (position A of FIG. 2) of the bundle of light rays according to the positons of the optical diodes of the pixels 820.

For example, the light rays (which are blurry light rays causing blur) of the circumferential portion of the bundle of light rays may be fully incident upon at least one pixel 821 (which is a left pixel of which the optical diode is formed at the left side about the pixel center) of the pixels 820 arranged at the circumferential portion of the bundle of light rays, and may not be incident upon the remaining pixels 822 (which are right pixels of which the optical diodes are formed at the right side about the pixel center).

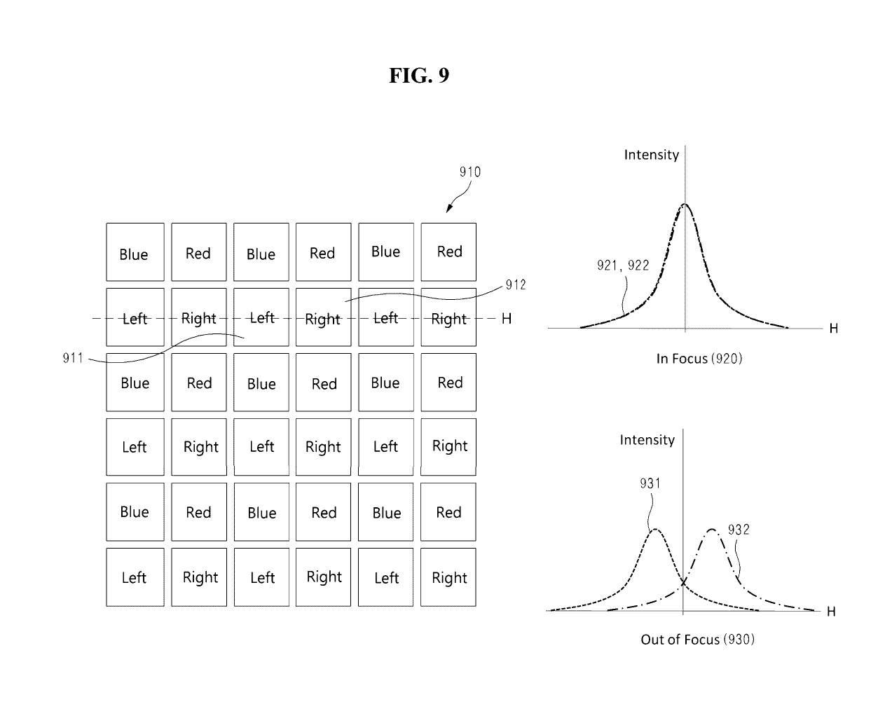

That is, according to the positions (central or circumferential positions) at which the pixels 81 and 820 are arranged based on the bundle of light rays, the at least one pixel 821 and the remaining pixels 822 receive light rays having mutually different light quantities, so that a disparity occurs between the images obtained through the at least one pixel 821 and the remaining pixels 822. The details will be described below with reference to FIG. 9.

FIG. 9 is a view illustrating the disparity between the images obtained from the pixels depicted with reference to FIGS. 8A and 8B.

Referring to FIG. 9, an image sensor 910 may include at least one pixel (hereinafter, referred to as a left pixel) 911 and remaining pixels (hereinafter, referred to as a right pixel) 912.

For example, the left pixel 911 may include an optical diode arranged at the left side about the pixel center, and the right pixel 912 may include an optical diode arranged at the right side about the pixel center. Thus, the optical diodes included in the left and right pixels 911 and 912 may be arranged at the positions which are offset against each other.

In this case, the left and right pixels 911 and 912 may process the same wavelength light ray or light rays having mutually different wavelengths. For example, the left and right pixels 911 and 912 may be G pixels for processing a G optical signal.

In this case, the image sensor may include the left and right pixels 911 and 912 which alternate with each other in one row.

When the image sensor is placed at a focal position (position 1 of FIG. 1A). the intensities of the light rays 921 and 922, which are incident upon the left and right pixels 911 and 912 arranged in one row, are shown in graph 1 920.

Meanwhile, when the image sensor is placed at a non-focal position (position 2 of FIG. 1A), the intensities of the light rays 931 and 932, which are incident upon the left and right pixels 911 and 912 arranged in one row, are shown in graph 2 930.

As shown in graph 2 930, since the positions at which the intensities of the light rays 931 and 932 incident upon the left pixel 911 and the right pixel 912 are maximized are different from each other, a disparity occurs between the images obtained through the left and right pixels 911 and 912.

Thus, the image sensor may perform refocusing and depth extraction based on the disparity between images by using the left and right pixels 911 and 912 which include optical diodes and are arranged at the positions offset against each other.

The specific schemes of performing refocusing and depth extraction using a disparity between images may be implemented by utilizing disparity-based refocusing and depth extraction algorithms well-known in the art. Thus, the detailed description about the specific schemes of performing refocusing and depth extraction will be omitted.

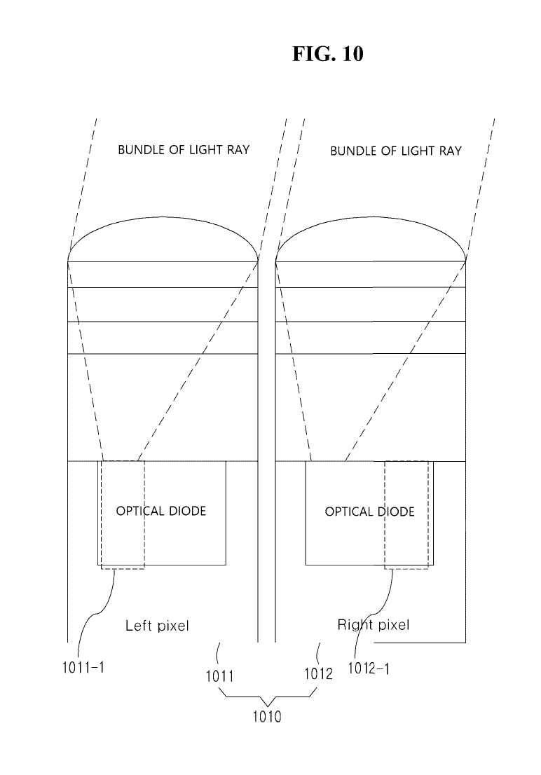

In addition, instead of using the left and right pixels 911 and 912 including the optical diodes arranged at the offset positions against each other, the image sensor may use left and right pixels arranged at the same position. In this case, the position at which the depletion regions of the optical diodes included in the left and right pixels are formed may be adjusted to be offset against each other. The details will be described below with reference to FIG. 10.

FIG. 10 is a view showing another example of the pixels depicted with reference to FIGS. 8A and 8B.

Referring to FIG. 10, as depicted with reference to FIGS. 8A and 8B, instead of configuring the optical diodes included in the pixels to be offset against each other, the optical diodes included in the pixels 1010 may be configured to be arranged at the same position (about the centers of the pixels 1010).

Meanwhile, in this case, the image sensor may be adjusted such that the positons at which the depletion regions 1011-1 and 1012-1 of the optical diodes included in the pixels 1010 are arranged are offset against each other. Hereinafter, it will be described that the depletion regions 1011-1 and 1012-1 of the optical diodes included in the pixels 1010 are arranged at left and right sides about each pixel center, but the embodiment is not limited thereto. The depletion regions may be placed at mutually different positions on three-dimensional plane about the centers of the pixels.

For example, at least one (left pixel) 1011 of the pixels 1010 may fully receive the light rays of the circumferential portion of the bundle of light rays by adjusting the position of the depletion region 1011-1 formed on the optical diode to be placed at the left side about the pixel center, and the remaining pixels (right pixel) 1012 may not receive the light rays of the circumferential portion of the bundle of light rays by adjusting the positions of the depletion regions 1012-1 formed on the optical diodes to be placed at the right side about the center of each pixel.

Therefore, the at least one pixel 1011 and the remaining pixels 1012 of the pixels 1010 receive light rays having mutually different light quantities, such that a disparity occurs between the images obtained through the at least one pixels 1011 and the remaining pixels 1012. Thus, as described above with reference to FIG. 9, the image sensor including the pixels 1010 may perform application functions of refocusing and depth extraction.

The foregoing devices may be realized by hardware elements, software elements and/or combinations thereof. For example, the devices and components illustrated in the exemplary embodiments of the inventive concept may be implemented in one or more general-use computers or special-purpose computers, such as a processor, a controller, an arithmetic logic unit (ALU), a digital signal processor, a microcomputer, a field programmable array (FPA), a programmable logic unit (PLU), a microprocessor or any device which may execute instructions and respond. A processing unit may implement an operating system (OS) or one or more software applications running on the OS. Further, the processing unit may access, store, manipulate, process and generate data in response to execution of software. It will be understood by those skilled in the art that although a single processing unit may be illustrated for convenience of understanding, the processing unit may include a plurality of processing elements and/or a plurality of types of processing elements. For example, the processing unit may include a plurality of processors or one processor and one controller. Also, the processing unit may have a different processing configuration, such as a parallel processor.

Software may include computer programs, codes, instructions or one or more combinations thereof and may configure a processing unit to operate in a desired manner or may independently or collectively control the processing unit. Software and/or data may be permanently or temporarily embodied in any type of machine, components, physical equipment, virtual equipment, computer storage media or units or transmitted signal waves so as to be interpreted by the processing unit or to provide instructions or data to the processing unit. Software may be dispersed throughout computer systems connected via networks and may be stored or executed in a dispersion manner. Software and data may be recorded in one or more computer-readable storage media.

The methods according to the above-described exemplary embodiments of the inventive concept may be implemented with program instructions which may be executed through various computer means and may be recorded in computer-readable media. The media may also include, alone or in combination with the program instructions, data files, data structures, and the like. The program instructions recorded in the media may be designed and configured specially for the exemplary embodiments of the inventive concept or be known and available to those skilled in computer software. Computer-readable media include magnetic media such as hard disks, floppy disks, and magnetic tape; optical media such as compact disc-read only memory (CD-ROM) disks and digital versatile discs (DVDs); magneto-optical media such as floptical disks; and hardware devices that are specially configured to store and perform program instructions, such as read-only memory (ROM), random access memory (RAM), flash memory, and the like. Program instructions include both machine codes, such as produced by a compiler, and higher level codes that may be executed by the computer using an interpreter. The described hardware devices may be configured to act as one or more software modules to perform the operations of the above-described exemplary embodiments of the inventive concept, or vice versa.

While a few exemplary embodiments have been shown and described with reference to the accompanying drawings, it will be apparent to those skilled in the art that various modifications and variations can be made from the foregoing descriptions. For example, adequate effects may be achieved even if the foregoing processes and methods are carried out in different order than described above, and/or the aforementioned elements, such as systems, structures, devices, or circuits, are combined or coupled in different forms and modes than as described above or be substituted or switched with other components or equivalents.

Thus, it is intended that the inventive concept covers other realizations and other embodiments of this invention provided they come within the scope of the appended claims and their equivalents.

What is claimed is:

1. An image sensor to which multiple fill factors are applied, the image sensor comprising
a plurality of pixels configured to process light rays having a plurality of wavelengths by wavelength,
wherein at least one of the pixels has a fill factor which is different from fill factors of remaining pixels other than the at least one pixel.

2. The image sensor of claim 1, wherein a position of an optical diode included in the at least one pixel is offset against positions of optical diodes included in the remaining pixels.

3. The image sensor of claim 1, wherein a position of a depletion region formed in an optical diode included in the at least one pixel is offset against positions of depletion regions formed in optical diodes included in the remaining pixels.

4. The image sensor of claim 1, wherein the image sensor performs depth extraction based on a disparity between an image obtained through the at least one pixel and images obtained through the remaining pixels.

5. The image sensor of claim 1, wherein the image sensor performs refocusing using a disparity between an image obtained through the at least one pixel and images obtained through the remaining pixels.

6. The image sensor of claim 1, wherein the at least one pixel comprises an optical diode which has a size smaller than sizes of optical diodes included in the remaining pixels.

7. The image sensor of claim 6, wherein the optical diode included in the at least one pixel has a ray incident area smaller than ray incident areas of the optical diodes included in the remaining pixels, such that only light rays corresponding to a central portion of a bundle of light rays are incident upon the optical diode of the at least one pixel.

8. The image sensor of claim 1, wherein a size of a depletion region formed in an optical diode included in the at least one pixel is adjusted such that the size of the depletion region formed in the optical diode included in the at least one pixel is different from sizes of depletion regions formed in optical diodes included in the remaining pixels.

9. The image sensor of claim 1, wherein the image sensor performs high-dynamic range imaging by using images obtained through the at least one pixel and the remaining pixels.

10. The image sensor of claim 1, wherein the image sensor performs depth extraction based on a blur change between images through the at least one pixel and the remaining pixels.

11. The image sensor of claim 1, further comprising a metal layer arranged between a micro-lens and an optical diode included in the at least one pixel to reduce a ray incident area of the optical diode, wherein a hole is formed in the metal layer.

12. The image sensor of claim 1, wherein the pixels comprise micro-lenses having a same form or size.

13. The image sensor of claim 1, wherein the pixels comprise a red cell, a green cell, a blue cell and a white cell, and wherein the white cell has a fill factor different from fill factors of the red, green and blue cells.

14. The image sensor of claim 1, wherein the pixels comprise a red cell, two green cells and a blue cell, and
wherein one of the two green cells has a fill factor different from fill factors of the red cell, the other green cell and the blue cell.

15. A camera system comprising:
a basic aperture;
a lens; and
an image sensor comprising a plurality of pixels configured to process light rays having a plurality of wavelengths by wavelength, the light rays passing through the basic aperture and the lens,
wherein at least one of the pixels has a fill factor which is different from fill factors of remaining pixels other than the at least one pixel.
